(19) United States
(12) Patent Application Publication
(10) Pub. No.: US 2009/0061085 A1
(43) Pub. Date: Mar. 5, 2009

(54) Expedited manufacture of carbon-carbon composite brake discs

(75) Inventors: Akshay Waghray, Granger, IN (US); David E. Parker, Granger, IN (US); David R. Cole, North Liberty, IN (US)

Correspondence Address: HONEYWELL INTERNATIONAL INC.;LAW DEPARTMENT AB 2, P.O. BOX 2245, MORRISTOWN, NJ, 07962, US

(73) Assignee: HONEYWELL INTERNATIONAL INC., Morris Township, NJ (US)

(21) Appl. No.: 11/896,590

(22) Filed: Sep. 4, 2007

(51) Int. Cl. C23C 16/26

(52) U.S. Cl. 427/249.1

(57) ABSTRACT

Method of manufacturing carbon-carbon composite brake disc by: (a) providing textile-based preform in shape of annular brake disc, the preform having a volume 30% or more greater than the volume of the brake disc to be manufactured; (b) subjecting the preform to a first CVD processing for not more than 7.5 days to density it to not more than 1.0 g/cc; (c) machining the densified preform to a shape having a volume no more than 15% greater than the volume of the carbon-carbon composite brake disc to be manufactured: and (d) subjecting the preform to one or two additional cycles of CVD processing, to further densify it to a density of more than 1.7 g/cc. The preform is then machined to provide the carbon-carbon composite brake disc. The total CVD processing time in steps (b) and (c) is no longer than about 32.5 days.

### FIELD OF THE INVENTION

The present invention relates to the manufacture of carbon-carbon composite brake discs. More particularly, the present invention provides improved throughput (that is, a faster overall manufacturing period) in the densification phase of the manufacture of carbon-carbon composite brake discs.

### BACKGROUND OF THE INVENTION

Brake discs for high performance applications, such as aircraft landing systems and racing cars, are often made from carbon-carbon composites. These composites are often manufactured by providing a carbon fiber preform in the general shape of the brake disc to be manufactured, densifying said carbon fiber preform by incorporating a pyrocarbon matrix thereinto, and machining the densified matrix into the desired final brake disc shape. A common manner of densifying the carbon fiber preform involves chemical vapor infiltration (CVI) or chemical vapor deposition (CVD). These two processes are well known in general to persons skilled in the art of composite brake disc manufacture, and for most purposes, including the present invention, are generally interchangeable. For the sake of simplicity, the present disclosure will sometimes refer to CVD alone. It should be understood, however, that in the context of the present invention, CVI is intended alternatively to CVD. Among the many patents which discuss details of CVI/CVD processing are U.S. Pat. No. 5,705,008 (FIBER-REINFORCED CARBON AND GRAPHITE ARTICLES AND METHOD FOR THE PRODUCTION THEREOF), U.S. Pat. No. 6,648,977 B2 (METHOD OF PRODUCING NEAR-NET SHAPE FREE STANDING ARTICLES BY CHEMICAL VAPOR DEPOSITION), and U.S. Pat. No. 6,780,462 B2 (PRESSURE GRADIENT CVI/CVD PROCESS), the disclosures of which are incorporated herein by reference.

Cycle time for chemical vapor infiltration and chemical vapor deposition of large commercial aircraft composite brakes ranges are typically about 40 days. This involves multiple CVI/CVD cycles with intermediate machining of parts having densities in excess of 1.2 g/cc after the first infiltration cycle. Typical annular preform disc dimensions for such brakes, and for automobile racing brakes which are likewise made from carbon-carbon composites, may range from 16 inches to 22 inches in outer diameter and from 8 inches to 14 inches in inner diameter.

Due to the high cost of carbon-carbon composite brake discs, the industry is perennially seeking ways to make the manufacturing process more economical. For instance, Liew et al., in U.S. Pat. No. 5,662,855 (METHOD OF MAKING NEAR NET SHAPED FIBROUS STRUCTURES) describe production of a structure that includes a plurality of helically wound fibrous tapes arranged to form a flat annulus having a plurality of interleaved fibrous layers which may be used in the production of brake discs. Among the myriad other patents relating to the manufacture of carbon-carbon composite brake discs are U.S. Pat. No. 6,365,257 B1 (CHORDAL PREFORMS FOR FIBER-REINFORCED ARTICLES AND METHOD FOR THE PRODUCTION THEREOF), U.S. Pat. No. 6,537,470 B1 (RAPID DENSIFICATION OF POROUS BODIES (PREFORMS) WITH HIGH VISCOSITY RESINS OR PITCHES USING A RESIN TRANSFER MOLDING PROCESS), and U.S. Pat. No. 7,153,543 B2 (REFRACTORY-CARBON COMPOSITE BRAKE FRICTION ELEMENTS). None of these patents teaches the improved processing provided by the present invention.

### SUMMARY OF THE INVENTION

The present invention includes infiltrating textile based preforms employing a short CVD cycle to rigidize the preforms and form preliminary composites. The density of the composites at this stage is less than 1 gram per cubic centimeter. The composites are then machined to near net shape. The disc grows slightly (about 2%) during high temperature treatment following the infiltration process and prior to final machining. This final high temperature treatment is generally required to achieve the desired frictional performance characteristics. A subsequent longer CVD infiltration cycle is then performed to provide the final density to the composite.

One embodiment of the present invention is a method of manufacturing a carbon-carbon composite brake disc that includes steps (a) to (d). Step (a) includes providing a textile-based preform roughly in the shape of an annular brake disc (e.g., a brake disc dimensioned to be useful in an aircraft landing system). In step (a), this preform will typically have a volume at least about 30% greater than the volume of the carbon-carbon composite brake disc to be manufactured. Step (b) includes subjecting the preform to a first CVD processing procedure, for not more than 7.5 days. Step (b) densifies the preform to a density of not more than approximately 1.0 g/cc. Step (c) includes machining the densified preform to a shape having a volume no more than about 15% greater than the volume of the carbon-carbon composite brake disc to be manufactured. Step (d) includes subjecting the preform produced by step (c) to one or two additional cycles of CVD processing, in order to further densify the preform to a density of more than 1.7 g/cc. Finally, this densified preform is machined to provide the final product carbon-carbon composite brake disc. In accordance with the present invention, the total CVD processing time in steps (b) and (c) is no longer than about 32.5 days.

There are at least three major different scenarios under which CVD processing can be conducted in this invention. In one, the first CVD processing step is conducted for from 2.5 to 7.5 days, and then a single second CVD cycle conducted for from 22.5 to 27.5 days. In another scenario, the first CVD processing step is conducted for from 2.5 to 7.5 days, and then two additional CVD cycles of the same duration are conducted, each for from 10 to 12.5 days. In a third scenario, the first CVD processing step is conducted for from 2.5 to 7.5 days, and subsequently two additional CVD cycles are conducted, the first of which is conducted for from 12.5 to 15 days and the second of which is conducted for less than 10 days.

In another embodiment of this invention, the method of manufacturing a carbon-carbon composite brake disc includes steps (i) to (v). In step (i), a textile-based preform is provided, roughly in the shape of an annular brake disc. The preform typically has a volume about 50% greater than the volume of the carbon-carbon composite brake disc to be manufactured. In step (ii), the preform is subjected to CVD processing for from about 3 to about 7 days, in order to densify it to a density of not more than approximately 1.0 g/cc. In step (iii), this low-density preform is machined to a shape having a volume which is no more than about 10% greater than the volume of the carbon-carbon composite brake disc to be manufactured. In step (iv), the preform is subjected to another cycle of CVD processing, for from about 10 to about 15 days, to further densify the preform. The resulting densified preform is machined to a shape having a volume no more than about 5% greater than the volume of the carbon-carbon composite brake disc to be manufactured. In step (v), the preform is subjected to a last cycle of CVD processing, of up to about 12 days, in order to further densify the preform to more than 1.7 g/cc. The resulting fully densified preform is subjected to final machining to provide the desired carbon-carbon composite brake disc product.

This invention results in a significant reduction in cycle time. This invention enables attainment of the desired density within about 30 days, with reduced infiltration cycles and machining operations. Thus the present invention provides a significant reduction in cycle time in the manufacture of brake discs, of approximately 25%. Since the composites are less bulky in the second infiltration cycle, a larger number of disks can be accommodated in the furnace, thereby further increasing the throughput in this critical constraint, particularly in the manufacture of aircraft and automotive race car brake discs. Another advantage of the present invention is that the machining of the composites while they still have low densities reduces wear on the diamond cutting tools.

### BRIEF DESCRIPTION OF THE DRAWING

FIG. 1 is a graphical representation of the reduction in CVD processing time provided by the present invention.

### DETAILED DESCRIPTION OF THE INVENTION

In practicing the method of manufacturing a carbon-carbon composite brake disc of the present invention, one first provides a textile-based preform roughly in the shape of an annular brake disc. Generally, the preform will have a volume at least about 30% greater than the volume of the carbon-carbon composite brake disc to be manufactured. In accordance with the present invention, one subjects the preform to a first CVD processing for not more than 7.5 days to densify it to a density of not more than approximately 1.0 grams per cubic centimeter. Subsequently, this slightly densified preform is machined to a shape having a volume no more than about 15% greater than the volume of the carbon-carbon composite brake disc to be manufactured. This is referred to as near net machining. Once the slightly densified preform has been subjected to near net machining, it is subjected to one or two additional cycles of CVD processing, in order to further densify the preform to a density of more than 1.7 g/cc. Final machining of this densified preform provides the desired carbon-carbon composite brake disc. In accordance with the present invention, the total CVD processing time in this manufacturing process is no longer than about 32.5 days.

The present invention contemplates variations in the manner in which the total CVD processing is conducted. In one embodiment, the first CVD processing step is conducted for from 2.5 to 7.5 days, and a single additional CVD cycle is conducted for from 22.5 to 27.5 days. In another embodiment, the first CVD processing step is conducted for from 2.5 to 7.5 days, and two additional cycles of CVD processing step are each conducted for from 10 to 12.5 days. In yet another embodiment, the first CVD processing step is conducted for from 2.5 to 7.5 days, a second CVD cycle is conducted for from 12.5 to 15 days, and a third CVD cycle is conducted for less than 10 days.

The following Table depicts various embodiments of the present invention:

| | 2-cycle | 3-cycle | 3-cycle | |
|---|---|---|---|---|
| | embodiment | embodiment A | embodiment B | |
| 1^{st} cycle | 2.5 to 7.5 days | 2.5 to 7.5 days | 2.5 to 7.5 | days |
| 2^{nd} cycle | 22.5 to 27.5 days | 10 to 12.5 days | 12.5 to 15 | days |
| 3^{rd} cycle | n.a. | 10 to 12.5 days | <10 | days |
| Total time | 25 days to | 22.5 days to 32.5 days | <32.5 | days |
| | 32.5 days | | | |

Persons skilled in the art of manufacturing carbon-carbon composite brake discs are familiar with the machining that is generally conducted during manufacture. Among the patents which provide disclosure relevant to such machining are U.S. Pat. No. 4,136,487 (ARRANGEMENT FOR ABRASIVE MACHINING OF SHAPED SURFACES), U.S. Pat. No. 4,519,732 (METHOD FOR THE MACHINING OF COMPOSITE MATERIALS), U.S. Pat. No. 4,680,897 (METHOD FOR MACHINING HOLES IN COMPOSITE MATERIALS), U.S. Pat. No. 5,816,755 (METHOD FOR MACHINING COMPOSITES), U.S. Pat. No. 6,261,1531 B1 (APPARATUS AND METHOD OF MACHINING BRAKE COMPONENTS), and U.S. Pat. No. 6,752,709 B1 (HIGH-SPEED, LOW-COST, MACHINING OF METAL MATRIX COMPOSITES), all of which are incorporated herein by reference.

### EXAMPLE

The following Table shows a change in volume comparison provided by the present invention as compared to a baseline during in-process machining between CVD cycles for a typical initial preform disc with an outer diameter of about 21 inches and an inner diameter of about 11½ inches.

| | Baseline | Near Net |
|---|---|---|
| | (% of final) | (% of final) |
| Pre-1^{st} CVD | 154 | 154 |
| Pre-2^{nd} CVD | 128 | 112 |
| Pre-3^{rd} CVD | 121 | 106 |
| Pre-4^{th} CVD | 117 | n.a. |
| Final | 100 | 100 |

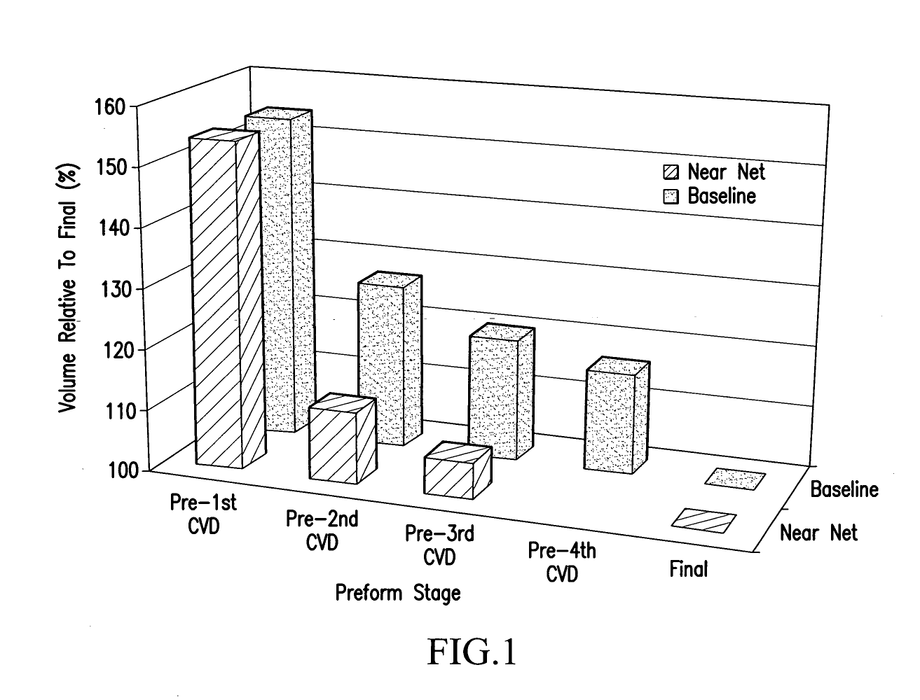

In both cases in this Example, the starting composite preform has a volume that is 1.54 times (154% of) the volume of the composite final product to be manulacturled. In baseline (that is, conventional) processing, the starting composite preform is subjected to 10 days of CVD processing (1^{st} CVD), then to another 10 days of CVD processing (2^{nd} CVD), then again to another 10 days of CVD processing (3^{rd} CVD), and finally to a last 10 days of CVD processing (4^{th} CVD), with some machining after each round of CVD processing. This conventional processing requires a total of 40 days of CVD processing. In contrast, the present invention subjects the starting composite preform to 5 days of CVD processing (1^{st} CVD), then to 12.5 days of CVD processing (2^{nd} CVD), and finally to a last 12.5 days of CVD processing (3^{rd} CVD), with some machining after each round of CVD processing. This Example of processing in accordance with the present invention thus requires a total of only 30 days of CVD processing to provide a composite having the same shape and density as the composite produced by the conventional processing. This data is present graphically in FIG. 1.

A key feature of the present invention is that the machining after the first, short CVD processing step is “near net” machining. That is, in the present Example, the near net machined composite is only about 10% larger (112% of) the volume of the composite final product to be manufactured.

Persons skilled in the art are well aware of the manner in which the brake discs provided by the novel processes disclosed herein may be used. For instance, a plurality of densified brake discs made in accordance with the present invention may be assembled to form a multi-disc brake similar to those described in detail in U.S. Pat. Nos. 4,018,482; 4,878,563; and 4,613,017.

Although detailed embodiments and limitations to the present invention have been described above, it should be apparent that various modifications are possible without departing from the spirit and scope of the present invention.

What is claimed is:

1. A method of manufacturing a carbon-carbon composite brake disc which comprises:
(a) providing a textile-based preform roughly in the shape of an annular brake disc, said preform having a volume at least about 30% greater than the volumie ofl the carbon-carbon composite brake disc to be manufactured;
(b) subjecting said preform to a first CVD processing for not more than 7.5 days to densify said preform to a density of not more than approximately 1.0 g/cc;
(c) machining said densified preform to a shape having a volume no more than about 15% greater than the volume of the carbon-carbon composite brake disc to be manufactured; and
(d) subjecting said preform to one or two additional cycles of CVD processing, to further density the preform to a density of more than 1.7 g/cc, and machining the densified preform to provide said carbon-carbon composite brake disc,
wherein the total CVD processing time in steps (b) and (c) is no longer than about 32.5 days.

2. The method of claim 1, wherein said first CVD processing step (b) is conducted for from 2.5 to 7.5 days, and wherein said one or two additional cycles of CVD processing step (c) is a single CVD cycle conducted for from 22.5 to 27.5 days.

3. The method of claim 1, wherein said first CVD processing step (b) is conducted for from 2.5 to 7.5 days, and wherein said one or two additional cycles of CVD processing step (c) is two CVD cycles each conducted for from 10 to 12.5 days.

4. The method of claim 3, wherein said first CVD processing step (b) is conducted for 5 days and wherein said two additional cycles of CVD processing step (c) are each conducted for 12.5 days, for a total of 30 days of CVD processing.

5. The method of claim 1, wherein said first CVD processing step (b) is conducted for from 2.5 to 7.5 days, and wherein said one or two additional cycles of CVD processing step (c) is two CVD cycles, the first of which is conducted for from 12.5 to 15 days and the second of which is conducted for less than 10 days.

6. The method of claim 1, wherein said carbon-carbon composite brake disc is dimensioned to be useful in an aircraft landing system.

7. A method of manufacturing a carbon-carbon composite brake disc which comprises:
(i) providing a textile-based preform roughly in the shape of an annular brake disc, said preform having a volume about 50% greater than the volume of the carbon-carbon composite brake disc to be manufactured;
(ii) subjecting said preform to CVD processing for from about 3 to about 7 days to densify said preform to a density of not more than approximately 1.0 g/cc;
(iii) machining said densified preform to a shape having a volume no more than about 10% greater than the volume of the carbon-carbon composite brake disc to be manufactured;
(iv) subjecting said preform to another cycle of CVD processing of from about 10 to about 15 days to further densify the preform and machining the resulting densified preform to a shape having a volume no more than about 5% greater than the volume of the carbon-carbon composite brake disc to be manufactured; and
(v) subjecting said preform to a final cycle of CVD processing of up to about 12 days to further densify the preform to more than 1.7 g/cc, and machining the resulting densified preform to provide said carbon-carbon composite brake disc.

8. The method of claim 7, wherein said carbon-car-bon composite brake disc is dimensioned to be useful in an aircraft landing system.

9. The method of claim 7, wherein the preform in step (a) has a volume that is 154% of the volume of the carbon-carbon composite brake disc to be manufactured, wherein machining in step (c) reduces the preform to a volume that is 112% of the volume of the carbon-carbon composite brake disc to be manufactured, and wherein machining in step (d) reduces the preform to a volume that is 106% of the volume of the carbon-carbon composite brake disc to be manufactured.

10. A method of reducing cycle time in the manufacture of aircraft and automotive race car brake discs, which method comprises the steps of:
(a) providing a textile-based preform roughly in the shape of an annular brake disc, said preform having a volume at least about 30% greater than the volumIe of the carbon-carbon composite brake disc to be manufactured;
(b) subjecting said preform to a first CVD processing for not more than 7.5 days to densify said preform to a density of not more than approximately 1.0 g/cc;
(c) machining said densified preform to a shape having a volume no more than about 15% greater than the volume of the carbon-carbon composite brake disc to be manufactured; and
(d) subjecting said preform to one or two additional cycles of CVD processing, to further densify the preform to a density of more than 1.7 g/cc, and machining the densified preform to provide said carbon-carbon composite brake disc.

11. The method of claim 10, wherein said reduction in cycle time is a reduction of approximately 25%.

12. The method of claim 10, wherein said method additionally provides reduced wear on diamond cutting tools employed in the machining processes of steps (c) and (d).
